(19) United States
(12) Patent Application Publication
(10) Pub. No.: US 2026/0165120 A1
(43) Pub. Date: Jun. 11, 2026

(54) HIGH THERMAL CONDUCTIVE AND ELECTROMAGNETIC INTERFERENCE SHIELDING ELECTRONIC PACKAGE STRUCTURE AND METHOD FOR MANUFACTURING THE SAME

(71) Applicant: REALTEK SEMICONDUCTOR CORP., HSINCHU (TW)

(72) Inventor: CHIH-YEN SU, HSINCHU (TW)

(21) Appl. No.: 19/272,235

(22) Filed: Jul. 17, 2025

(30) Foreign Application Priority Data
Dec. 5, 2024 (TW) 113147101

(51) Int. Cl. H01L 23/367; H01L 21/48; H01L 21/683; H01L 23/00; H01L 23/373; H01L 23/498; H01L 23/552

(52) U.S. Cl. CPC H10W 40/22; H10P 72/74; H10W 40/258; H10W 42/20; H10W 70/023; H10W 70/093; H10W 70/66; H10W 70/69; H10W 74/15; H10W 90/724; H10W 90/734

(57) ABSTRACT

A high thermal conductive and electromagnetic interference shielding electronic package structure and a method for manufacturing the same. The electronic package structure includes a circuit substrate, a die, an electromagnetic shielding layer, a passivation layer, a dielectric layer, a welding composite layer, a thermal-conductive metal layer, and a heat dissipation cover. The electromagnetic shielding layer is arranged on the die. The passivation layer is disposed on the electromagnetic shielding layer. The dielectric layer is disposed on the passivation layer. The heat dissipation cover is disposed on the thermal-conductive metal layer. An inner tin layer of the heat dissipation cover and the thermal-conductive metal layer jointly form an intermetallic compound layer to firmly connect the heat dissipation cover to a welding base layer of the welding composite layer.

### CROSS-REFERENCE TO RELATED PATENT APPLICATION

This application claims the benefit of priority to Taiwan Patent Application No. 113147101, filed on Dec. 5, 2024. The entire content of the above identified application is incorporated herein by reference.

Some references, which may include patents, patent applications and various publications, may be cited and discussed in the description of this disclosure. The citation and/or discussion of such references is provided merely to clarify the description of the present disclosure and is not an admission that any such reference is “prior art” to the disclosure described herein. All references cited and discussed in this specification are incorporated herein by reference in their entireties and to the same extent as if each reference was individually incorporated by reference.

### FIELD OF THE DISCLOSURE

The present disclosure relates to a high thermal conductive and electromagnetic interference shielding electronic package structure and a method for manufacturing the same, and more particularly to an electronic package structure in which a die is provided with a high thermal conductivity and electromagnetic interference shielding structure and a method for manufacturing the electronic package structure.

### BACKGROUND OF THE DISCLOSURE

With the advancement of semiconductor process technology, heat generated by semiconductor chips continues to increase. Hence, heat dissipation means for semiconductor chips are becoming increasingly important. Currently, the heat dissipation paths of semiconductor chips can be mainly divided into: first, conduction to a printed circuit board and a package surface through a package structure; and second, heat transfer to the atmosphere through convection and radiation from the printed circuit board and the package surface. Therefore, if heat can be quickly transferred to the printed circuit board and the package surface, good heat dissipation performance can be achieved.

Furthermore, high-power radio frequency chips also need to face the problem of electromagnetic waves. External electromagnetic waves may interfere with the semiconductor chip and cause performance degradation. Therefore, it is necessary to effectively isolate the electromagnetic waves to limit the interference to the semiconductor chips.

In a conventional technology, a metal cover is provided at the periphery of the semiconductor chip, and a thermal interface material (TIM), such as a common silicon-based thermal paste, is coated between the metal cover and the chip to reduce the contact thermal resistance. However, the thermal conductivity of silicon-based thermal paste is low, usually 3˜8 W/(m·K), so that heat is transferred to the metal cover slowly. In addition, long-term high-temperature environments often cause the silicon-based thermal paste to harden, which greatly affects the overall heat dissipation efficiency.

In order to achieve the electromagnetic shielding effect, another conventional technology uses conductive adhesive to connect a metal cover to a ground terminal of a substrate. However, when the metal cover is connected to the ground terminal of the substrate, the conductive adhesive is easily connected to other circuits due to manufacturing processes or environmental temperature differences, causing a short circuit.

Therefore, how to improve the electronic package structure and enhance the heat dissipation and electromagnetic shielding effects of the electronic package structure for overcoming the above problems has become an important issue to be solved in the relevant field.

### SUMMARY OF THE DISCLOSURE

In response to the above-referenced technical inadequacies, the present disclosure provides a high thermal conductive and electromagnetic interference shielding electronic package structure, so as to improve both the thermal conductivity between a die and a heat dissipation cover, and the electromagnetic shielding effect of the die.

In order to address the aforementioned problems, one technical aspect adopted by the present disclosure is to provide a high thermal conductive and electromagnetic interference (EMI) shielding electronic package structure, which includes a circuit substrate, a die, an electromagnetic shielding layer, a passivation layer, a dielectric layer, a welding composite layer, a thermal-conductive metal layer, a heat dissipation cover, and a plurality of solder balls. The circuit substrate includes an upper surface, a lower surface, and at least one ground trace disposed on the upper surface. The die has a bottom surface, a top surface, a plurality of side surfaces, and at least one ground via. The at least one ground via extends from the bottom surface to the top surface. The bottom surface of the die is disposed on the upper surface of the circuit substrate, and the at least one ground via is electrically connected to the at least one ground trace of the circuit substrate. The electromagnetic shielding layer is disposed on the top surface and the plurality of side surfaces of the die. The passivation layer is disposed on the electromagnetic shielding layer. The dielectric layer is disposed on the passivation layer. The solder composite layer includes a welding base layer and a tin layer. The welding base layer is disposed on the dielectric layer. The tin layer is disposed on the welding base layer. The thermal-conductive metal layer is disposed on the tin layer. The heat dissipation cover is disposed on the thermal-conductive metal layer. The heat dissipation cover has an inner tin layer. The thermal-conductive metal layer and the inner tin layer collectively form an intermetallic compound layer to fixedly connect the heat dissipation cover to the welding base layer. The plurality of solder balls are disposed on the lower surface of the circuit substrate.

In order to solve the above-mentioned problems, another one of the technical aspects adopted by the present disclosure is to provide a method for manufacturing a high thermal conductive and electromagnetic interference shielding electronic package structure, which includes the steps of: placing a diced die on a temporary carrier, the die having a bottom surface, a top surface, a plurality of side surfaces, and at least one ground via connecting the bottom surface to the top surface; forming an electromagnetic shielding layer on the top surface and the plurality of side surfaces of the die; forming a passivation layer on the electromagnetic shielding layer; forming a dielectric layer on the passivation layer;
forming a welding composite layer on the dielectric layer, the welding composite layer including a welding base layer and a tin layer; removing the temporary carrier; placing the die in a flip-chip manner on an upper surface of a circuit board and filling a underfill material on the bottom surface of the die, in which the bottom surface of the die is disposed on the upper surface of the circuit board, and the at least one ground via of the die is connected to at least one ground trace of the circuit board; disposing a thermal-conductive metal layer on the welding composite layer; providing a heat dissipation cover located on the thermal-conductive metal layer, the heat dissipation cover having an inner tin layer; forming a plurality of solder balls on a lower surface of the circuit board; and performing a reflow ball grid array attachment process to fix the a plurality of solder balls to the lower surface of the circuit board and simultaneously applying a passivation gas to constrain a flow of the thermal-conductive metal layer, in which the thermal-conductive metal layer and the inner tin layer are heated together to form an intermetallic compound layer to fixedly connect the heat dissipation cover to the welding base layer.

Therefore, in the high thermal conductive and electromagnetic interference shielding electronic package structure provided by the present disclosure, by virtue of the electromagnetic shielding layer is disposed on the die, the thermal-conductive metal layer is connected to the top surface of the die, and the die is connected to the ground trace of the circuit board through its ground via, thereby providing EMI shielding. In addition, the transient liquid phase bonding process is utilized to bond an indium sheet as the thermal-conductive metal layer with the tin layer to form an intermetallic compound layer, which can securely connect the heat dissipation cover to the welding composite layer and dissipate the residual heat of the die outward through the heat dissipation cover. In comparison with the conventional thermal paste connection manner, the high thermal conductive and EMI shielding electronic package structure of the present disclosure has a better thermal conductivity effect.

These and other aspects of the present disclosure will become apparent from the following description of the embodiment taken in conjunction with the following drawings and their captions, although variations and modifications therein may be affected without departing from the spirit and scope of the novel concepts of the disclosure.

### BRIEF DESCRIPTION OF THE DRAWINGS

The described embodiments may be better understood by reference to the following description and the accompanying drawings, in which:

FIG. 1A is a schematic view of a die arranged on a temporary carrier of the present disclosure;

FIG. 1B is a schematic view showing an electromagnetic shielding layer, a passivation layer and a dielectric layer being formed on the die according to the present disclosure;

FIG. 1C is a schematic view showing a welding composite layer according to the present disclosure;

FIG. 1D is a schematic view showing the temporary carrier according to the present disclosure;

FIG. 1E is a schematic view showing the die being disposed on a circuit substrate in a flip-chip manner according to the present disclosure;

FIG. 1F is a schematic view showing a thermal-conductive metal layer being disposed on a welding composite layer according to the present disclosure;

FIG. 1G is a schematic view of disposing a heat dissipation cover on a periphery of the die according to the present disclosure;

FIG. 2A is a bottom view of the heat dissipation cover of the present disclosure;

FIG. 2B is a cross-sectional view taken along line IIB-IIB of FIG. 2A;

FIG. 2C is a cross-sectional view of the heat dissipation cover with an inner tin layer and a solder mask layer of the present disclosure;

FIG. 3 is a schematic view showing a reflow process of the electronic package structure according to the present disclosure;

FIG. 4 is a cross-sectional schematic view of a heat dissipation cover according to a second embodiment of the present disclosure;

FIG. 5A is a cross-sectional schematic view showing an electronic package structure according to the second embodiment of the present disclosure; and

FIG. 5B is a schematic view showing the reflow process of the electronic package structure according to the second embodiment of the present disclosure.

### DETAILED DESCRIPTION OF THE EXEMPLARY EMBODIMENTS

The present disclosure is more particularly described in the following examples that are intended as illustrative only since numerous modifications and variations therein will be apparent to those skilled in the art. Like numbers in the drawings indicate like components throughout the views. As used in the description herein and throughout the claims that follow, unless the context clearly dictates otherwise, the meaning of “a,” “an” and “the” includes plural reference, and the meaning of “in” includes “in” and “on.” Titles or subtitles can be used herein for the convenience of a reader, which shall have no influence on the scope of the present disclosure.

The terms used herein generally have their ordinary meanings in the art. In the case of conflict, the present document, including any definitions given herein, will prevail. The same thing can be expressed in more than one way. Alternative language and synonyms can be used for any term(s) discussed herein, and no special significance is to be placed upon whether a term is elaborated or discussed herein. A recital of one or more synonyms does not exclude the use of other synonyms. The use of examples anywhere in this specification including examples of any terms is illustrative only, and in no way limits the scope and meaning of the present disclosure or of any exemplified term. Likewise, the present disclosure is not limited to various embodiments given herein. Numbering terms such as “first,” “second” or “third” can be used to describe various components, signals or the like, which are for distinguishing one component/signal from another one only, and are not intended to, nor should be construed to impose any substantive limitations on the components, signals or the like.

The present disclosure provides a method for manufacturing a high thermal conductive and electromagnetic interference shielding electronic package structure, which includes the following processes.

### First Embodiment

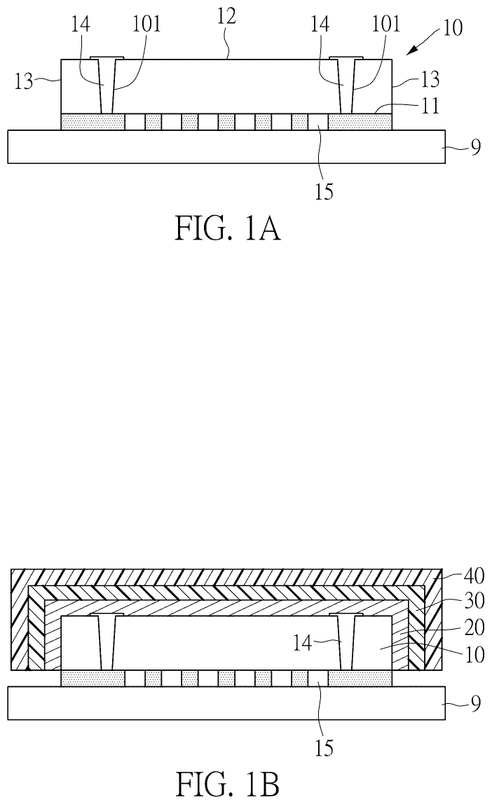

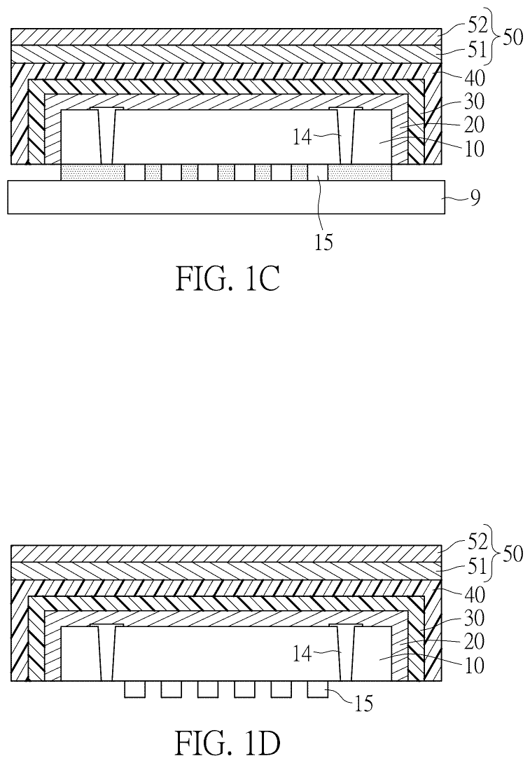

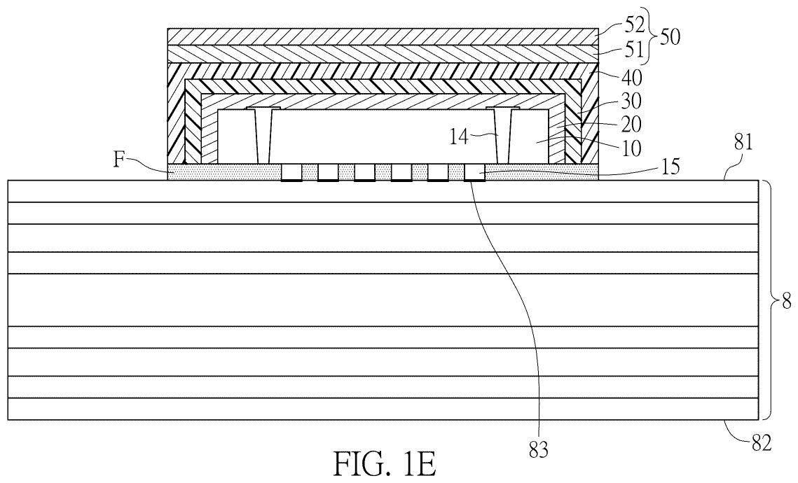

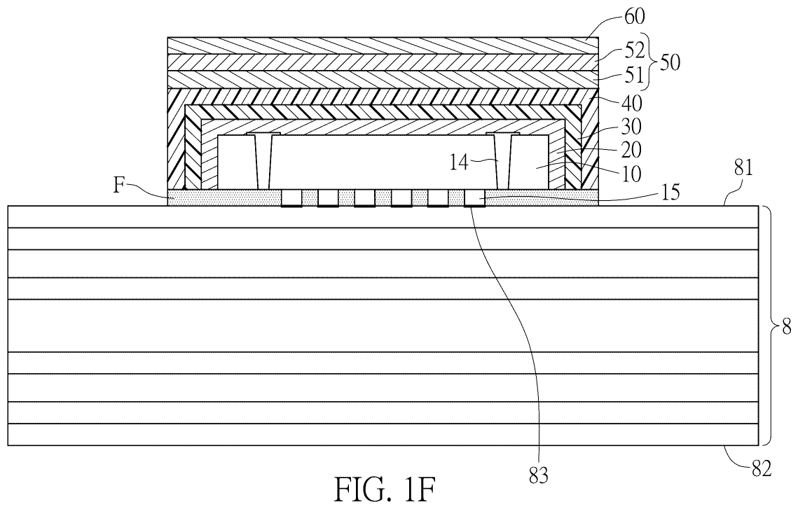

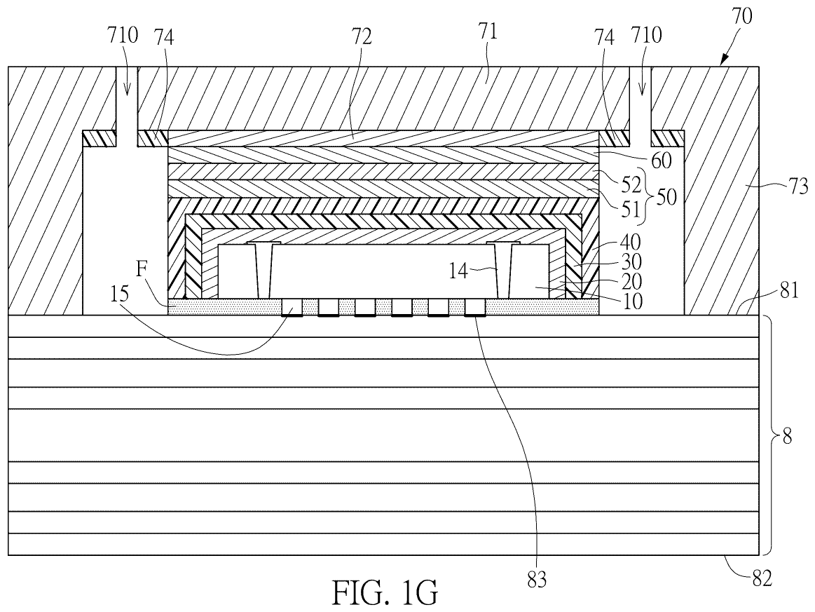

Referring to FIG. 1A, a cut die 10 is placed on a temporary carrier 9. The die 10 is formed by cutting a whole wafer (not shown) in which a circuit layer (not shown), via holes and conductive bumps 15 are formed thereon. Specifically, the die 10 has a lower surface 11, a top surface 12, and multiple side surfaces 13. The lower surface 11 is an active surface and has circuit components, and the top surface 12 and the side surfaces 13 are passive surfaces. The die 10 has at least one ground via 101. The ground via 101 connects the lower surface 11 to the top surface 12. In this embodiment, the ground via 101 may be a through silicon via (TSV). An inside of the ground via 101 is filled with a conductive material 14, so as to penetrate the die 10 to provide a vertical interconnection.

Referring to FIG. 1B, an electromagnetic shielding layer 20 is formed on the top surface 12 and the plurality of side surfaces 13 of the die 10. The electromagnetic shielding layer 20 in this embodiment is a transparent conductive layer, for example, indium tin oxide (ITO), which can be deposited by a sputtering deposition method to the surface of the die 10. The indium tin oxide is a mixture of 90% indium oxide (In₂O₃) and 10% tin oxide (SnO₂), with the main characteristic being a combination of electrical conductivity and optical transparency. ITO has the characteristics of low resistivity and high light transmittance at the same time. When ITO is made into a thin film, it meets the requirements of good conductivity and light transmittance. The material of indium tin oxide is made of indium oxide and tin oxide, and the oxide powder is mixed in a certain proportion, pressed into an ingot shape, and subjected to sintering heat treatment to form a sputtering target.

However, the present disclosure is not limited thereto. The transparent conductive layer may be indium tin oxide, indium oxide, tin oxide, antimony tin oxide, zinc oxide, zinc aluminum oxide, zinc gallium oxide, or graphene formed by sputtering. The electromagnetic shielding layer 20 contacts the ground via 101 of the die 10 and can be grounded to provide an electromagnetic shielding function.

Next, a passivation layer 30 is formed on the electromagnetic shielding layer 20. The passivation layer 30 in this embodiment is an insulating protective layer formed of inorganic materials, such as silicon glass, silicon nitride, or composed of silicon oxide. The passivation layer 30 can be formed on the die 10 through chemical vapor deposition (CVD), or can also be formed using other suitable dielectric materials and techniques.

Then, a dielectric layer 40 is formed on the passivation layer 30. The dielectric layer 40 in this embodiment is made of polymer material, such as epoxy resin, and polyimide (PI) resin, and can be formed by sputtering.

Referring to FIG. 1C, a welding composite layer 50 is formed on the dielectric layer 40. The welding composite layer 50 includes a welding base layer 51, and a tin layer 52. The welding base layer 51 of this embodiment can be a copper-nickel layer. Copper itself is easily oxidized. The inactive nickel plating layer can protect the copper layer and prevent copper from diffusing into the tin layer 52 during connection. Specifically, the nickel layer is used to prevent the copper layer and the tin layer from mutual migration and diffusion. The nickel layer can be used as a barrier layer and anti-corrosion protective layer to protect the copper layer from oxidation and prevent deterioration of the conductivity and the soldering ability. In this embodiment, the steps of forming the welding composite layer 50 include first electroplating a copper-nickel layer on the dielectric layer 40, and plating a tin layer 52 on the upper surface of the copper-nickel layer. The thickness of the tin layer 52 may be 15 μm.

Referring to FIG. 1D, the temporary carrier 9 is removed by debonding. In other words, the die 10 having the completed welded composite layer 50 is removed from the temporary carrier 9.

Referring to FIG. 1E, the die 10 is placed on the upper surface 81 of a circuit substrate 8 in a flip-chip manner, and an underfill material F is filled on the lower surface 11 of the die 10. The underfill material F fully fills in a gap between the lower surface 11 of the die 10 and the circuit substrate 8. The lower surface 11 of the die 10 is disposed on the upper surface 81 of the circuit substrate 8, so that the conductive bumps 15 of the die 10 are connected to the circuits on the upper surface 81 of the circuit substrate 8 accordingly. Thereby, the ground via 101 of the die 10 is connected to the ground trace 83 of the circuit substrate 8 through the internal conductor and the conductive bump 15. In this embodiment, the electromagnetic shielding layer 20 contacts the ground via 101 of the die 10, and is in contact with the ground trace 83 of the circuit substrate 8 and can be grounded to provide an electromagnetic shielding function.

Referring to FIG. 1F, a thermal-conductive metal layer 60 is disposed on the welding composite layer 50. In this embodiment, the thermal-conductive metal layer 60 is an indium sheet. The method of arranging the thermal-conductive metal layer 60 can be preheating and pasting the indium sheet for serving as the thermal-conductive metal layer 60. The thermal conductivity of pure indium is 86 W/Mk with good ductility and can completely fill the gap between two material interfaces, helping to improve the overall thermal conductivity of the heat dissipation module. The melting point of indium is 157° C. At this melting point, indium can be melted and combined with other metals. Compared with other metals such as gold and copper with good thermal conductivity, indium has a lower operating temperature.

However, the present disclosure is not limited thereto. The thermal-conductive metal layer can be a low-temperature alloy made of indium and tin or bismuth. At this step, the structure from the die 10 to the thermal-conductive metal layer 60 can be referred to as a package body.

Referring to FIG. 1G, a heat dissipation cover 70 is provided and located on the thermal-conductive metal layer 60. The heat dissipation cover 70 is preferably made of a metal material with a higher thermal conductivity, such as copper or aluminum.

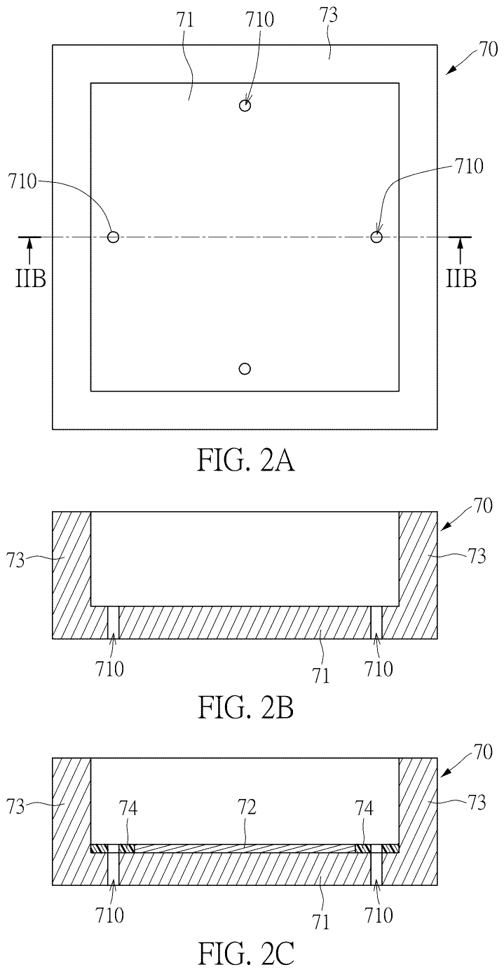

As shown in FIGS. 2A to 2C, the heat dissipation cover 70 of this embodiment includes a top wall 71 and a side wall 73. The side wall 73 is connected to the periphery of the top wall 71. The top wall 71 forms a plurality of vents 710. The heat dissipation cover 70 in this embodiment has four vents 710, but the present disclosure is not limited thereto. The number of vents 710 may be at least one. The vents 710 are fluidly communicated to the outer surface of the thermal-conductive metal layer 60. The inner surface of the top wall 71 of the heat dissipation cover 70 is provided with an inner tin layer 72 and a solder mask layer 74. The solder mask layer 74 is located on an outer periphery of the inner tin layer 72 and around the vents 710. The thickness of the inner tin layer 72 can be 15 μm.

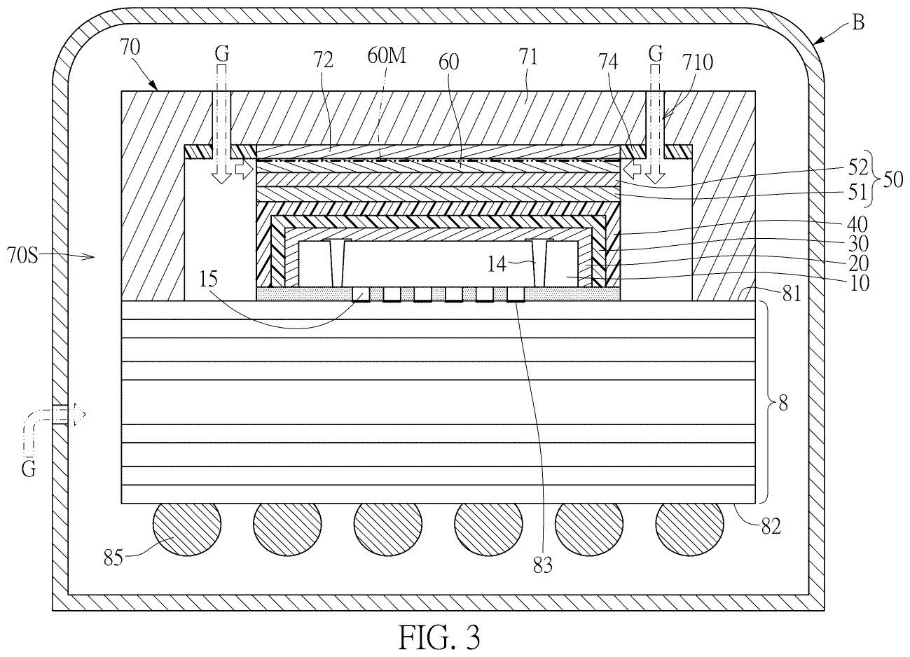

As shown in FIG. 3, the heat dissipation cover 70 surrounds the die 10 to form a covering space 70S. The side wall 73 of the heat dissipation cover 70 abuts the upper surface 81 of the circuit substrate 8.

The temperature is raised to the melting point of the thermal-conductive metal layer 60, for example, the melting point of indium is 156.6° C., and then the heat dissipation cover 70 is attached. The heat dissipation cover 70 has an inner tin layer 72, and the thermal-conductive metal layer 60 and the inner tin layer 72 are heated to form an intermetallic compound layer (IMC layer) 60M, so as to fixedly connect the heat dissipation cover 70 to the welding base layer 51. In this embodiment, the inner tin layer 72 and the indium layer are connected through a transient liquid phase bonding (TLP bonding) technology to form an indium tin alloy layer to connect the heat dissipation cover 70 to the welding base layer 51. The intermetallic compound layer 60M is an indium tin alloy, or intermetallic compound.

Transient liquid phase (TLP) diffusion bonding technology utilizes a welding material with a melting point lower than the base material for welding connection. When heated to the melting point of the welding material, the welding material liquefies and forms a transient liquid phase at the bonding interface. During the isothermal process, bonding occurs as the lower melting point welding material diffuses into the base material to form an intermetallic compound (IMCs), and the thickness of the transient liquid phase decreases accordingly. With transient liquid phase diffusion bonding technology, the base material does not melt, enabling the joining of virtually any metal or non-metal bonding material without degrading the properties of the base material. In addition, this provides the bonding interface with good quality, high bonding precision, and minimal deformation of both the base material and the bonding material.

As shown in FIG. 3, the ball grid array (BGA) attachment process involves printing multiple solder balls 85 onto a lower surface 82 of a circuit board 8, followed by a reflow process to secure the solder balls 85 to the lower surface 82 of the circuit board 8.

The temperature during the reflow process can reach as high as 245° C. to 260° C., which is above the melting point of indium (156.6° C.). Consequently, the indium layer may melt and flow out during the reflow process. To prevent the flow of the indium layer, the present disclosure simultaneously applies a passivation gas G (e.g., nitrogen gas) within the reflow oven B during the reflow process to constrain the flow of the thermal-conductive metal layer 60 (indium layer).

As shown in FIG. 3, the passivation gas G enters the covering space 70S of the heat dissipation cover 70 through the vents 710 of the heat dissipation cover 70, creating a saturated gas pressure inside the heat dissipation cover 70 to constrain the flow of the molten thermal-conductive metal layer 60. The passivation gas G surrounds the thermal-conductive metal layer 60, and the molten indium can be fixed by the gas pressure without overflowing. The application of the passivation gas G is terminated after the ball grid array (BGA) attachment process is completed. When the reflow step of the BGA attachment process ends and returns to room temperature, the thermal-conductive metal layer 60, such as an indium sheet, returns to a solid state.

Finally, the high thermal conductive and electromagnetic interference (EMI) shielding electronic package structure of the present disclosure is completed, which includes a circuit board 8, a die 10, an electromagnetic shielding layer 20, a passivation layer 30, a dielectric layer 40, a welding composite layer 50, and a thermal-conductive metal layer 60. The bottom surface 11 of the die 10 is disposed on the upper surface 81 of the circuit board 8, and the ground via 101 is electrically connected to the ground trace 83 of the circuit board 8. The electromagnetic shielding layer 20 is disposed on the top surface 12 and the plurality of side surfaces 13 of the die 10, and is connected to the ground trace 83 of the circuit board 8 through the ground via 101 and the conductive bumps 15, thereby enabling the electromagnetic shielding layer 20 to provide EMI shielding. The passivation layer 30 is disposed on the electromagnetic shielding layer 20. The dielectric layer 40 is disposed on the passivation layer 30. The welding composite layer 50 includes a welding base layer 51 and a tin layer 52. The welding base layer 51 is disposed on the dielectric layer 40, and the tin layer 52 is disposed on the welding base layer 51. The thermal-conductive metal layer 60 is disposed on the tin layer 52. The heat dissipation cover 70 is disposed on the thermal-conductive metal layer 60. The thermal-conductive metal layer 60 and the inner tin layer 72 of the heat dissipation cover 70 together form an intermetallic compound layer 60M to fixedly connect the heat dissipation cover 70 to the welding composite layer 50. Finally, multiple solder balls 85 are disposed on the lower surface 82 of the circuit board 8.

### Second Embodiment

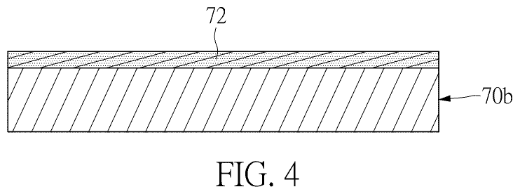

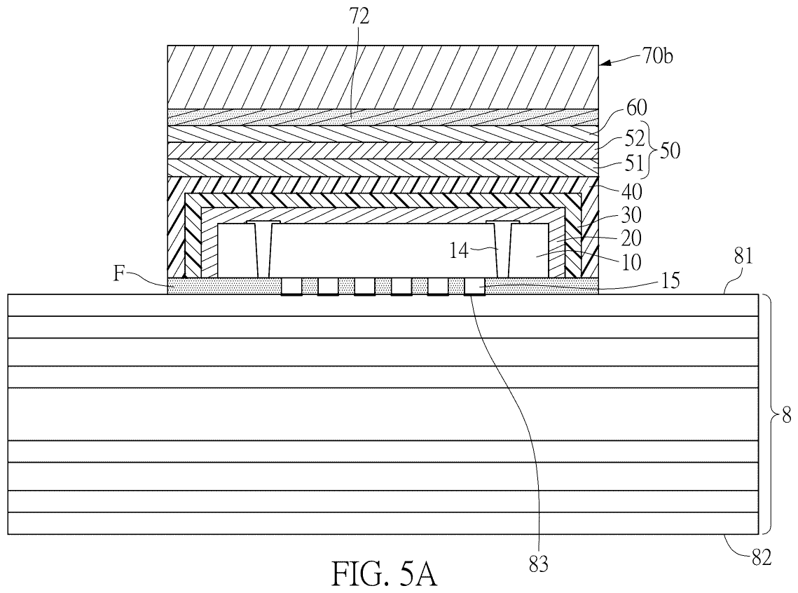

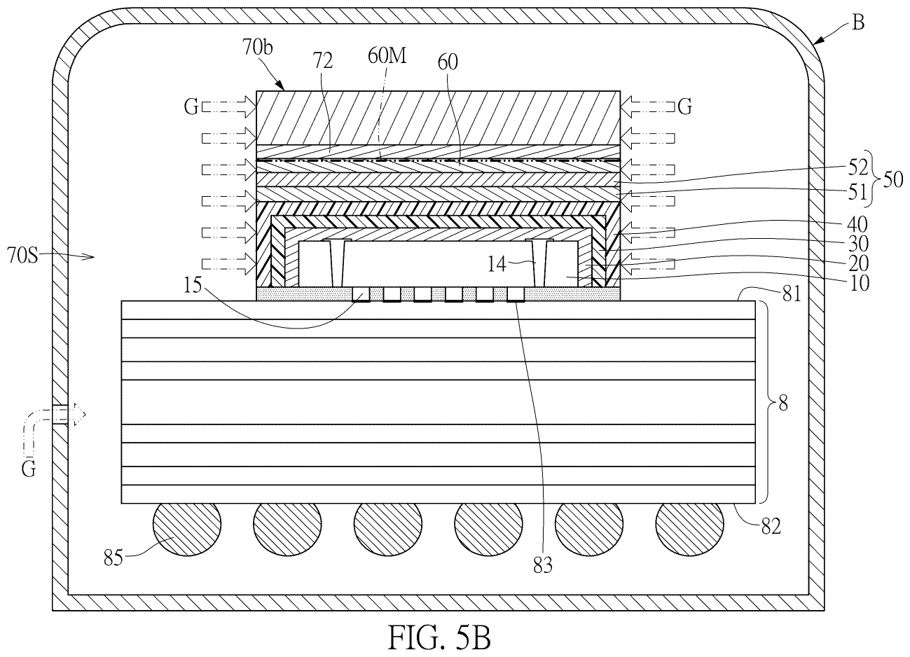

Referring to FIG. 4, a second embodiment of the present disclosure is provided and has the same steps from FIG. 1A to FIG. 1F, and the difference between the previous embodiment resides in the shape of the heat dissipation cover 70b. The heat dissipation cover 70b in this embodiment has a shape that corresponds to the shape of the die 10. In other words, the heat dissipation cover 70b can be a sheet-like structure, substantially square.

The temperature is raised to the melting point of the thermal-conductive metal layer 60 (indium layer), and then the heat dissipation cover 70b is attached, allowing the tin layer 52 and the indium layer to form an indium-tin alloy layer through transient liquid phase bonding process to connect the heat dissipation cover 70b to the welding base layer 51.

Finally, a reflow BGA attachment process is performed in a sealed reflow oven B. A passivation gas G (e.g., nitrogen gas) is applied within the reflow oven B to surround the package body and constrain the flow of the thermal-conductive metal layer 60.

Additionally, in the present disclosure, the thermal-conductive metal layer 60 (indium layer) can also be preheated and attached after the reflow BGA attachment process. Then, the temperature is raised to the melting point of the thermal-conductive metal layer 60 (indium layer), and then the heat dissipation cover is attached, so as to connect the heat dissipation cover to the welding base layer 51. In this process, it is not necessary to raise the temperature to the reflow temperature, and the process of applying the passivation gas can be omitted.

### Beneficial Effects of the Embodiments

In conclusion, in the high thermal conductive and electromagnetic interference shielding electronic package structure according to the present disclosure, by virtue of the electromagnetic shielding layer is disposed on the die, the thermal-conductive metal layer is connected to the top surface of the die, and the die is connected to the ground trace of the circuit board through its ground via, thereby providing EMI shielding.

The present disclosure utilizes the transient liquid phase bonding process to bond an indium sheet as the thermal-conductive metal layer with the tin layer to form an intermetallic compound layer, which can securely connect the heat dissipation cover to the welding composite layer and dissipate the residual heat of the die outward through the heat dissipation cover. In comparison with the conventional thermal paste connection manner, the high thermal conductive and EMI shielding electronic package structure of the present disclosure has a better thermal conductivity effect.

The foregoing description of the exemplary embodiments of the disclosure has been presented only for the purposes of illustration and description and is not intended to be exhaustive or to limit the disclosure to the precise forms disclosed. Many modifications and variations are possible in light of the above teaching.

The embodiments were chosen and described in order to explain the principles of the disclosure and their practical application so as to enable others skilled in the art to utilize the disclosure and various embodiments and with various modifications as are suited to the particular use contemplated. Alternative embodiments will become apparent to those skilled in the art to which the present disclosure pertains without departing from its spirit and scope.

What is claimed is:

1. A high thermal conductive and electromagnetic interference shielding electronic package structure, comprising:
a circuit board including an upper surface, a lower surface, and at least one ground trace disposed on the upper surface;
a die having a bottom surface, a top surface, a plurality of side surfaces, and at least one ground via connecting the bottom surface to the top surface, the bottom surface of the die being disposed on the upper surface of the circuit board, the at least one ground via being electrically connected to the at least one ground trace of the circuit board;
an electromagnetic shielding layer disposed on the top surface and the plurality of side surfaces of the die;
a passivation layer disposed on the electromagnetic shielding layer;
a dielectric layer disposed on the passivation layer;
a welding composite layer including a welding base layer and a tin layer, the welding base layer being disposed on the dielectric layer, and the tin layer being disposed on the welding base layer;
a thermal-conductive metal layer disposed on the tin layer;
a heat dissipation cover disposed on the thermal-conductive metal layer, the heat dissipation cover having an inner tin layer, wherein the thermal-conductive metal layer and the inner tin layer together form an intermetallic compound layer to fixedly connect the heat dissipation cover to the welding base layer; and
a plurality of solder balls disposed on the lower surface of the circuit board.

2. The high thermal conductive and electromagnetic interference shielding electronic package structure according to claim 1, wherein an underfill material is further applied between the bottom surface of the die and the circuit board.

3. The high thermal conductive and electromagnetic interference shielding electronic package structure according to claim 1, wherein the electromagnetic shielding layer is a transparent conductive layer, wherein a material of the transparent conductive layer is selected from the group consisting of indium tin oxide, indium oxide, tin oxide, antimony tin oxide, zinc oxide, aluminum zinc oxide, gallium zinc oxide, and graphene.

4. The high thermal conductive and electromagnetic interference shielding electronic package structure according to claim 1, wherein the passivation layer is made of an inorganic material and is selected from the group consisting of silicon glass, silicon nitride, and silicon oxide.

5. The high thermal conductive and electromagnetic interference shielding electronic package structure according to claim 1, wherein the dielectric layer is made of a polymer material and is selected from the group consisting of epoxy resin and polyimide resin.

6. The high thermal conductive and electromagnetic interference shielding electronic package structure according to claim 1, wherein the welding base layer is a copper-nickel layer, and the tin layer is located on an upper surface of the copper-nickel layer.

7. The high thermal conductive and electromagnetic interference shielding electronic package structure according to claim 1, wherein the thermal-conductive metal layer is an indium layer, and the indium layer and the tin layer are bonded to an indium-tin alloy layer through a transient liquid phase bonding process to connect the welding base layer and the heat dissipation cover.

8. The high thermal conductive and electromagnetic interference shielding electronic package structure according to claim 1, wherein the heat dissipation cover includes a top wall and a side wall, the top wall includes at least one vent fluidly communicating to an outer surface of the heat dissipation cover and located at a periphery of the die, and the side wall of the heat dissipation cover abuts the upper surface of the circuit board.

9. The high thermal conductive and electromagnetic interference shielding electronic package structure according to claim 8, wherein an inner surface of the top wall of the heat dissipation cover further includes a solder mask layer, and the solder mask layer is located at a periphery of the inner tin layer and surrounds the at least one vent.

10. The high thermal conductive and electromagnetic interference shielding electronic package structure according to claim 1, wherein a shape of the heat dissipation cover corresponds to a shape of the die.

11. A method for manufacturing a high thermal conductive and electromagnetic interference shielding electronic package structure, comprising:
placing a die that is diced on a temporary carrier, the die having a bottom surface, a top surface, a plurality of side surfaces, and at least one ground via connecting the bottom surface to the top surface;
forming an electromagnetic shielding layer on the top surface and the plurality of side surfaces of the die;
forming a passivation layer on the electromagnetic shielding layer;
forming a dielectric layer on the passivation layer;
forming a welding composite layer on the dielectric layer, the welding composite layer including a welding base layer and a tin layer;
removing the temporary carrier;
placing the die in a flip-chip manner on an upper surface of a circuit board and filling a underfill material on the bottom surface of the die; wherein the bottom surface of the die is disposed on the upper surface of the circuit board, and the at least one ground via of the die is connected to at least one ground trace of the circuit board;
disposing a thermal-conductive metal layer on the welding composite layer;
providing a heat dissipation cover located on the thermal-conductive metal layer, the heat dissipation cover having an inner tin layer;
forming a plurality of solder balls on a lower surface of the circuit board; and
performing a reflow ball grid array attachment process to fix the a plurality of solder balls to the lower surface of the circuit board and simultaneously applying a passivation gas to constrain a flow of the thermal-conductive metal layer; wherein the thermal-conductive metal layer and the inner tin layer are heated together to form an intermetallic compound layer to fixedly connect the heat dissipation cover to the welding base layer.

12. The method according to claim 11, wherein the electromagnetic shielding layer is a transparent conductive layer, and wherein the material of the transparent conductive layer is selected from the group consisting of indium tin oxide, indium oxide, tin oxide, antimony tin oxide, zinc oxide, aluminum zinc oxide, gallium zinc oxide, and graphene.

13. The method according to claim 11, wherein the passivation layer is made of an inorganic material and is selected from the group consisting of silicon glass, silicon nitride, and silicon oxide.

14. The method according to claim 11, wherein the dielectric layer is made of a polymer material and is selected from the group consisting of epoxy resin and polyimide resin.

15. The method according to claim 11, wherein the process of forming the welding composite layer includes a process of: electroplating a copper-nickel layer on the dielectric layer and plating the tin layer on an upper surface of the copper-nickel layer.

16. The method according to claim 11, further comprising a step of preheating and attaching the thermal-conductive metal layer, wherein the thermal-conductive metal layer is an indium layer.

17. The method according to claim 16, further comprising a step of raising the temperature to a melting point of the indium layer and then attaching the heat dissipation cover, wherein the tin layer and the indium layer are configured to form an indium-tin alloy layer through a transient liquid phase bonding process to connect the heat dissipation cover to the welding base layer.

18. The method according to claim 17, wherein the heat dissipation cover includes a top wall and a side wall, and at least one vent formed in the top wall, so that the at least one vent connects an outer surface of the thermal-conductive metal layer, the side wall connects the top wall and abuts the circuit board, the heat dissipation cover surrounds the die to form a covering space; and wherein the passivation gas enters the covering space through the at least one vent to constrain and fix the thermal-conductive metal layer of a molten state.

19. The method according to claim 18, wherein an inner surface of the top wall of the heat dissipation cover further includes a solder mask layer, and the solder mask layer is located at a periphery of the inner tin layer and surrounds the at least one vent.

20. The method according to claim 16, further comprising a step of providing the thermal-conductive metal layer having a shape that corresponds to a shape of the die, providing a sealed reflow oven for performing the reflow ball grid array attachment process, and applying the passivation gas within the reflow oven to constrain the flow of the thermal-conductive metal layer.
